(19) United States
(12) Patent Application Publication
(10) Pub. No.: US 2006/0115919 A1
(43) Pub. Date: Jun. 1, 2006

(54) Method of making a microelectromechanical (MEM) device using porous material as a sacrificial layer

(76) Inventors: Bishnu P. Gogoi, Scottsdale, AZ (US); Jin Zheng, Houghton, MI (US)

Correspondence Address: INGRASSIA FISHER & LORENZ, P.C., 7150 E. CAMELBACK, STE. 325, SCOTTSDALE, AZ, 85251, US

(21) Appl. No.: 11/000,547

(22) Filed: Nov. 30, 2004

(51) Int. Cl. H01L 21/00; H01L 21/302

(52) U.S. Cl. 438/50; 438/52; 438/53; 438/741

(57) ABSTRACT

A method of making a microelectromechanical (MEM) device using a standard silicon wafer, rather than an SOI wafer, includes selectively implanting a dopant in regions of the standard wafer, to thereby form heavily doped regions therein. The heavily doped regions are then converted to porous silicon regions. An electrical isolation layer is selectively deposited on the wafer and over a portion of one or more of the porous silicon regions. An epitaxial layer is grown over the porous silicon regions and the electrical isolation area, and device elements are formed in the epitaxial layer. Thereafter, at least portions of the porous silicon regions are removed, to thereby release the formed device elements.

### TECHNICAL FIELD

The present invention generally relates to microelectromechanical (MEM) devices and, more particularly, to a MEM device that is made by using porous material as the sacrificial layer.

### BACKGROUND

Many devices and systems include various numbers and types of sensors. The varied number and types of sensors are used to perform various monitoring and/or control functions. Advancements in micromachining and other microfabrication techniques and associated processes have enabled manufacture of a wide variety of microelectromechanical (MEM) devices, including various types of sensors. Thus, in recent years, many of the sensors that are used to perform monitoring and/or control functions are implemented using MEM sensors.

Although MEM devices, such as sensors, may be formed using various techniques and from various starting materials, many MEM devices are formed from a so-called Silicon-on-Insulator (SOI) wafer. As is generally known, an SOI wafer typically includes a silicon substrate, an active single-crystalline silicon layer, and a sacrificial layer of silicon dioxide between the silicon substrate and the active layer. Typically, to form a MEM device from an SOI wafer, the active layer may first be masked, patterned, and selectively etched to form the basic device elements. The sacrificial layer is then selectively removed by, for example, an etching process, to release at least some of the device elements.

Although MEM devices formed from SOI wafers are generally robust, safe, and reliable, device formation from SOI wafers does suffer certain drawbacks. For example, the cost of SOI wafers can be relatively high, which can concomitantly increase device and/or system costs. In an effort to address at least this drawback, some MEM devices have been formed in a standard silicon substrate, using porous silicon as the sacrificial layer. However, the MEM devices that have thus far been formed using a porous silicon sacrificial layer are limited in function. This is due, at least in part, to the fact that these devices do not include electrically isolated regions.

Hence, there is a need for a method of making a MEM device that does not use an SOI wafer as the starting material. In addition, there is a need for a method of making a MEM device using porous silicon as the sacrificial layer and that includes one or more electrically isolated regions therein. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawing figures, wherein like numerals denote like elements, and wherein:

FIG. 1 is a simplified cross section view of an exemplary MEM device that may be made in accordance with an embodiment of the present invention;

FIGS. 2-9 are simplified cross section views of the MEM device shown in FIG. 1, illustrating the various exemplary methodological steps that are used to make various MEM devices in accordance with an embodiment of the present invention;

FIG. 10 is a top view of a physical implementation of the MEM device shown in FIG. 1 that may be manufactured according the exemplary inventive process illustrated in FIGS. 2-9 and described herein.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

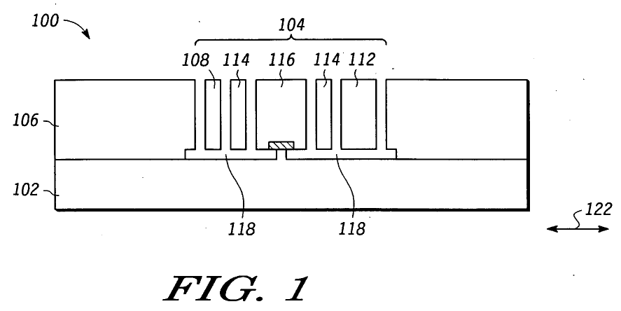

Turning now to the description, and with reference first to FIG. 1, an exemplary microelectromechanical (MEM) device 100 is shown. The depicted MEM device 100, which is shown in simplified cross section form, is an inertial sensor, such as an accelerometer, and includes a standard silicon substrate 102, and various device elements 104 formed in an epitaxial silicon layer 106. The standard silicon substrate 102 is a standard, single crystal silicon substrate that has been lightly doped (e.g., a dopant concentration of about 10¹² to 10¹⁵ cm⁻³) with a dopant of a first conductivity type. Thus, the silicon substrate 102 may be either a p⁻ substrate or an n⁻ substrate. In a particular preferred embodiment, however, the substrate 102 is an n⁻ substrate.

The device elements 104 that are formed in the epitaxial silicon layer 106 may vary, but in the depicted embodiment, in which the device 100 is an accelerometer, the device elements 104 include a suspension spring 108, a seismic mass 112, a pair of moving electrodes 114, and a fixed electrode 116. The spring 108 resiliently suspends the seismic mass and moving electrodes 114 above the substrate 102. As will be described in more detail further below, a plurality of horizontal trenches 118 are formed in the substrate 102, which release the spring 108, seismic mass 112, and moving electrodes 114 from the substrate 102, and allows these device elements 104 to be suspended there above.

As is generally known, an accelerometer 100 constructed as shown in FIG. 1, is typically implemented as a capacitance type accelerometer. That is, when the accelerometer 100 experiences an acceleration, the seismic mass 112 will move, due to the flexibility of the suspension spring 108, a distance that is proportional to the magnitude of the acceleration being experienced. The moving electrodes 114 are connected to the seismic mass 112, though this connection is not shown in FIG. 1, and thus move the same distance as the seismic mass 112, either toward or away from the fixed electrode 116. In the depicted embodiment, for a given acceleration along the x-axis 122, one moving electrode 114 will move toward the fixed electrode 116, and the other moving electrode 114 will move away from the fixed electrode 116. The distance that the moving electrodes 114 move either toward or away from the fixed electrode 116 will result in a proportional change in capacitance between the fixed electrode 116 and the individual moving electrodes 114. This change in capacitance may be measured and used to determine the magnitude of the acceleration.

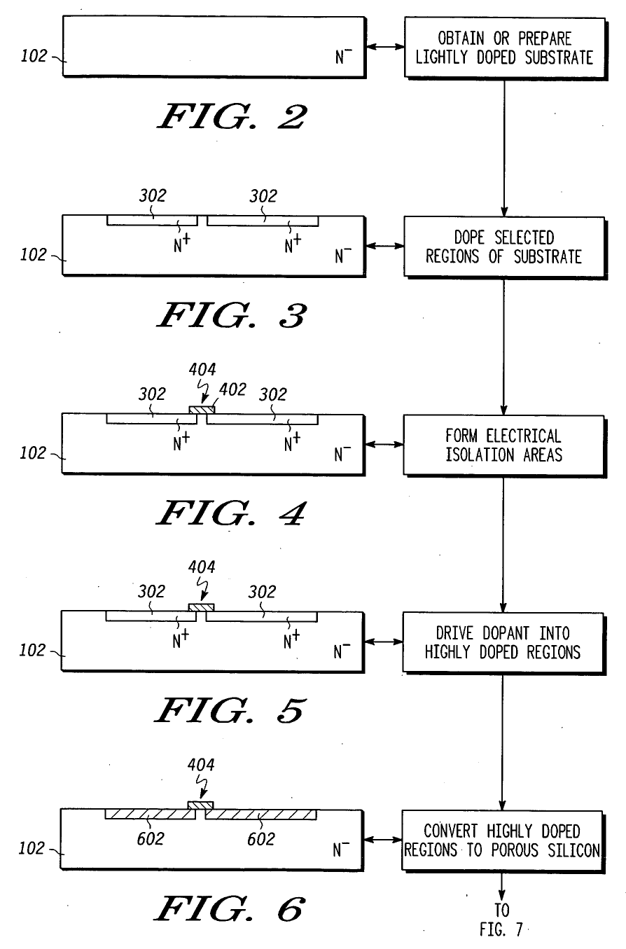

Having described a particular device 100 that may be formed in accordance with the present invention. A particular preferred process of forming the described device 100 will now be described. In doing so reference should be made, as appropriate, to FIGS. 2-9. It will be appreciated that the inventive process described below may be used to make any one of numerous types of MEM devices, and is not limited to use in making an accelerometer, such as the one shown in FIG. 1 and described above. It will additionally be appreciated that although the method is, for convenience, described using a particular order of steps, the method could also be performed in a different order or using different types of steps than what is described below.

With the above background in mind, reference should first be made to FIG. 2, which depicts the preferred starting material for the device 100 to be made. As was noted above, the preferred starting material is a standard, single crystal, lightly doped silicon substrate 102. In a preferred embodiment, as was also noted above, the substrate is preferably an n-type (n⁻) substrate, though it could alternatively be a p-type (p⁻) substrate. It will be appreciated that the preferred starting substrate 102 may be lightly doped before it is obtained for use, or it could be lightly doped as part of the overall process.

Having obtained (or prepared) the substrate 102, selected regions 302 of the substrate 102, as shown in FIG. 3, are doped with the same dopant type (e.g., n-type or p-type) as the substrate 102. The dopant concentration in these selected regions 302 is significantly higher (e.g., a dopant concentration of about 10¹⁷-10²⁰ cm⁻³ for n-type dopant) than the lightly doped substrate 102, thus making the regions 302 heavily doped regions (e.g., n⁺ or p⁺). In the depicted embodiment, in which the substrate 102 is a lightly doped n-type substrate, the heavily doped regions 302 are n-type regions (e.g., n⁺ regions). It will be appreciated that the dopant may be implanted using any one of numerous types of implantation or other doping mechanisms now known or developed in the future including, for example, ion implantation, and diffusion from gas, liquid, or solid dopant sources.

Turning now to FIG. 4, it is seen that once the heavily doped regions 302 are formed in the substrate 102, a layer of electrical isolation material 402 is deposited on the substrate 102. The electrical isolation material 402 is used to provide electrical isolation between selected device elements 104 of the finally formed device 100. In a particular preferred embodiment, the electrical isolation material 402 is silicon nitride. However, it will be appreciated that the electrical isolation material 402 may be implemented using any one of numerous suitable materials now known or developed in the future including, for example, low stress silicon rich silicon nitride.

No matter the particular type of electrical isolation material 402 that is used, after it is deposited, the electrical isolation material 402 is then patterned and etched, using any one of numerous conventional patterning and etching processes, to form the desired configuration and number of electrically isolated anchor regions 404. In the simplified MEM device 100 described herein, only a single anchor region 404 is shown; however, it will be appreciated that the configuration and number of anchor regions 404 may vary, depending on, for example, the particular MEM device 100 being implemented. It will additionally be appreciated that a masking layer (not shown) may be deposited over the heavily doped regions 302, or the entire surface of the substrate 102, prior to applying the electrical isolation layer 402. The masking layer, if applied, reduces the likelihood of any damage occurring during the electrical isolation material 402 etch process.

In the preferred embodiment, once the electrically isolated anchor regions 404 are formed, the dopants are then driven into the heavily doped regions 302. In a particular preferred embodiment, the dopants are driven in using a conventional furnace annealing process. It will be appreciated, however, that this is merely exemplary, and that any one of numerous other dopant drive-in, or diffusion, processes now known or developed in the future may also be used. It will additionally be appreciated that the dopants may be driven into the heavily doped regions 302 before the electrically isolated anchor regions 404 are formed, or before the electrical isolation material 402 is even deposited onto the substrate 102.

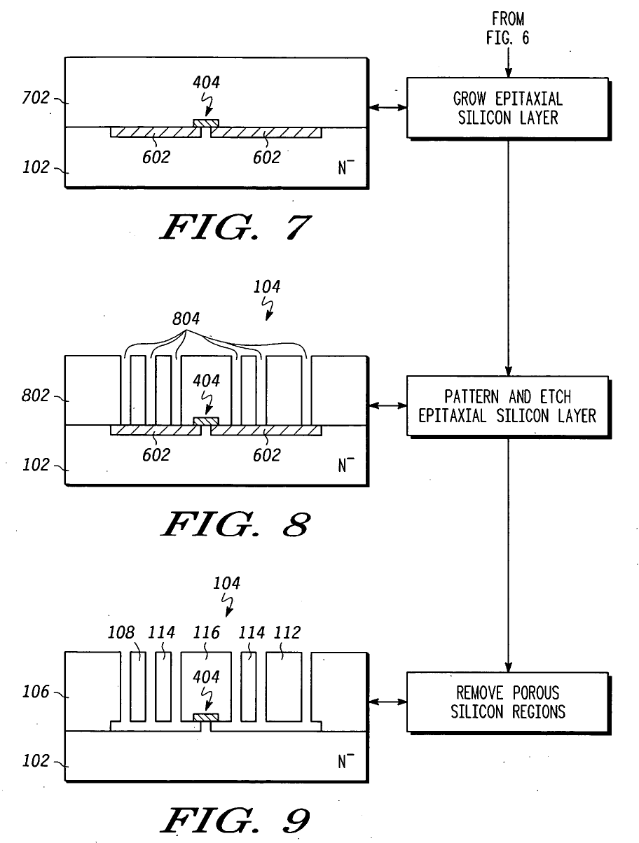

Turning now to FIG. 6, it is seen that once the dopants are driven in, the heavily doped regions 302 are converted to porous silicon regions 602. Once again, the process used to convert the heavily doped regions 302 to porous silicon regions 602 may vary, but in a particular preferred embodiment the conversion process is a conventional anodic electrochemical etch process carried out in a hydrofluoric (HF) bath. As is generally known, the various etch parameters associated with this process, such as HF concentration and/or current density, can affect both porous silicon formation rate and the size of the pores in the porous silicon that is formed. Preferably, the etch parameters are controlled, in a conventional manner, so that the size of the pores enables the porous silicon to be readily removed while at the same time allowing epitaxial silicon to be formed thereon. For example, the pore sizes may range from about 1 nm (nanometers) to about 20 nm. It will be appreciated that other known processes for forming porous silicon include, for example, a conventional chemical etching process. However, while usable, this process is not preferred as it exhibits a slower formation rate.

Once the porous silicon regions 602 have been formed, a layer of epitaxial silicon 702 is grown on the substrate 102. The epitaxial silicon layer 702 may be grown using any one of numerous known epitaxy growth processes including, but not limited to, vapor phase epitaxy, liquid phase epitaxy, low pressure epitaxy, and molecular beam epitaxy. Preferably, the epitaxial silicon layer 702 is grown to the desired thickness (t) of the device elements 104 that will be formed. Exemplary thicknesses range from about 10 microns to about 50 microns. However, it will be appreciated that the epitaxial silicon layer 702 could be grown to a larger thickness, and then portions thereof subsequently removed.

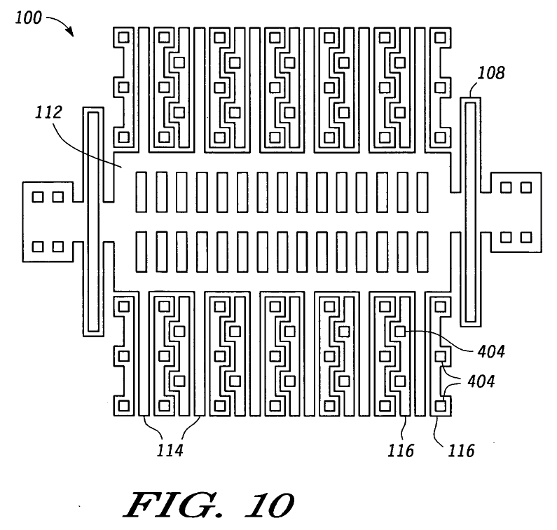

After the epitaxial silicon layer 702 of desired thickness is grown, and as shown in FIG. 8, the epitaxial silicon layer is patterned and etched 802 to define the device elements 104, and a plurality of etch openings 804. As with other portions of the process, the patterning and etching process used to define the device elements 104 in the epitaxial silicon layer 802 may vary, and may be any one of numerous processes now known or developed in the future. In a preferred embodiment, however, a dry reactive ion etch (DRIE) process is used. Depending on the particular MEM device 100 being formed, some or all of the etch openings 804 formed in the patterned and etched epitaxial silicon layer 802 may extend through to the porous silicon regions 602. In the depicted embodiment, in which the MEM device 100 is a high aspect ratio accelerometer, all of the etch openings 804 extend through the patterned and etched epitaxial silicon layer 802 to the porous silicon regions 602.

With reference now to FIG. 9, once the device elements 104 are appropriately defined, the device 100 is released by removing the porous silicon regions 602, thereby undercutting at least some of the device elements 104. The porous silicon regions 602, which function as a sacrificial layer, may be removed using any one of numerous types of etch processes including, for example, room temperature TMAH (tetramethyl ammonium hydroxide) or KOH (potassium hydroxide). In a particular preferred embodiment, room temperature TMAH is used due to its high selectivity to single crystal silicon. In the depicted embodiment, the suspension spring 108, seismic mass 112, and moving electrodes 114 are fully undercut, and thus released. However, the fixed electrode 116 is only partially undercut, and remains anchored, via the electrically isolated region 404, to the substrate 102.

The process described above and illustrated in FIGS. 2-9 may, as has been previously mentioned, be used to make any one of numerous MEM devices. A particular physical implementation of one such MEM device 100 is illustrated in FIG. 10. The MEM device depicted therein is, similar to that shown in FIGS. 1 and 9, an accelerometer. Thus, like reference numerals in FIGS. 1, 9, and 10 refer to like component parts. Hence, it is seen that the MEM device 100 includes a suspension spring 108 disposed on either side of a seismic mass 112. A plurality of moving electrodes 114 are each coupled to the seismic mass 112, and move therewith. One or more fixed electrodes 116 are disposed proximate tp, and spaced apart from, one or more of the moving electrodes 114. The fixed electrodes 116 are anchored to the substrate (not shown in FIG. 10) via a plurality of electrically isolated anchor regions 402.

The process described herein allows MEM devices, including high aspect ratio inertial sensors, to be made at a relatively less cost than is currently done. The process uses porous silicon as the sacrificial layer, and selectively formed electrically isolated regions, to implement the MEM device. The porous silicon is formed in a standard, single crystal silicon wafer, thus providing significant cost savings over present starting materials, such as SOI wafers. As was previously noted, the process is not limited to the specific order in which it was herein described. Rather, various steps could be performed before or after the steps that were described herein as preceding or proceeding it, respectively.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A method of forming a device on a substrate, comprising the steps of:
selectively doping one or more regions of the substrate with a dopant of the first conductivity type, to thereby form one or more heavily doped regions;
selectively forming one or more electrical isolation regions on at least selected regions of the substrate;
converting the heavily doped regions to porous silicon regions;
growing an epitaxial silicon layer over the porous silicon regions and the one or more electrical isolation regions;
forming device elements in the epitaxial silicon layer; and
removing at least a portion of the porous silicon regions to thereby release at least some of the formed device elements.

2. The method of claim 1, further comprising:
driving the selectively implanted dopant to form the heavily doped regions.

3. The method of claim 2, wherein the implanted dopant is driven into the heavily doped regions using a thermal process.

4. The method of claim 1, wherein the dopant is n-type dopant.

5. The method of claim 1, wherein the heavily doped regions are converted to the porous silicon regions using an electrochemical etch process.

6. The method of claim 1, wherein the porous silicon regions include pores having a predetermined size, the predetermined pore size being sufficient to allow the epitaxial silicon layer to grow thereon.

7. The method of claim 6, wherein the predetermined pore size in the range of from about 1 nm to about 20 nm.

8. The method of claim 1, further comprising:
after selectively doping regions of the substrate with the dopant, thermally driving the dopant into the heavily doped regions.

9. The method of claim 1, further comprising:
depositing a layer of an electrical isolation material; and
patterning and etching the deposited layer of electrical isolation material to form the one or more electrical isolation regions.

10. The method of claim 9, further comprising:
applying a mask layer over at least the porous silicon regions at least prior to etching the deposited electrical isolation material layer.

11. The method of claim 1, wherein the one or more electrical isolation regions each comprise silicon nitride.

12. The method of claim 1, wherein the one or more electrical isolation regions each comprise low stress silicon rich silicon nitride.

13. The method of claim 1, wherein the one or more electrical isolation regions are sized to allow growth of the epitaxial silcon layer thereon.

14. The method of claim 1, wherein the device that is formed is a microelectromechanical (MEM) device.

15. The method of claim 1, wherein the porous silicon regions are at least partially removed using either tetramethyl ammonium hydroxide (TMAH) or potassium hydroxide (KOH).

16. The method of claim 1, further comprising:
lightly doping the substrate with the dopant of the first conductivity type, to thereby form a lightly doped substrate,
wherein the one or more heavily doped regions are formed in the lighly doped substrate.

17. The method of claim 1, wherein the substrate comprises a single crystal material.

18. The method of claim 1, wherein the substrate comprises single crystal silicon.

19. A method of forming a device on a lightly doped substrate, the substrate lightly doped with a dopant of a first conductivity type, the method comprising the steps of:
selectively doping regions of the lightly doped substrate with the dopant of the first conductivity type, to thereby form heavily doped regions;
selectively forming one or more electrical isolation regions on at least selected regions of the lightly doped substrate;
converting the heavily doped regions to porous silicon regions;
growing an epitaxial layer over the porous silicon regions and each deposited electrical isolation area;
forming device elements in the epitaxial layer; and
removing at least a portion of the porous silicon regions to thereby release at least a portion of the formed device elements.

20. The method of claim 19, further comprising:
driving the selectively implanted dopant to form the heavily doped regions.

21. The method of claim 20, wherein the implanted dopant is driven into the heavily doped regions using a thermal process.

22. The method of claim 19, wherein the dopant is n-type dopant.

23. The method of claim 19, wherein the heavily doped regions are converted to the porous silicon regions using an electrochemical etch process.

24. The method of claim 19, wherein the porous silicon regions include pores having a predetermined size, the predetermined pore size being sufficient to allow the epitaxial silicon layer to grow thereon.

25. The method of claim 24, wherein the predetermined pore size in the range of from about 1 nm to about 20 nm.

26. The method of claim 19, further comprising:
after selectively doping regions of the lightly doped substrate with the dopant, thermally driving the dopant into the heavily doped regions.

27. The method of claim 19, further comprising:
depositing a layer of an electrical isolation material; and
patterning and etching the deposited electrical isolation material layer to form the electrical isolation regions.

28. The method of claim 27, further comprising:
applying a mask layer over at least the porous silicon regions at least prior to etching the deposited electrical isolation material layer.

29. The method of claim 19, wherein the electrical isolation regions each comprise silicon nitride.

30. The method of claim 19, wherein the electrical isolation regions each comprise low stress silicon rich silicon nitride.

31. The method of claim 19, wherein the electrical isolation regions are sized to allow growth of the epitaxial silicon layer thereon.

32. The method of claim 19, wherein the device that is formed is a microelectromechanical (MEM) device.

33. The method of claim 19, wherein the porous silicon regions are at least partially removed using either tetramethyl ammonium hydroxide (TMAH) or potassium hydroxide (KOH).

34. The method of claim 19, wherein the substrate comprises a single crystal material.

35. The method of claim 19, wherein the substrate comprises single crystal silicon.
